(19) United States
(12) Patent Application Publication
(10) Pub. No.: US 2007/0035010 A1
(43) Pub. Date: Feb. 15, 2007

(54) Circuit substrate

(76) Inventor: Julian Lee, Taipei Hsien (TW)

Correspondence Address: PRO-TECHTOR INTERNATIONAL SERVICES, 20775 NORADA CT., SARATOGA, CA, 95070, US

(21) Appl. No.: 11/199,884

(22) Filed: Aug. 9, 2005

(51) Int. Cl. H01L 23/15

(52) U.S. Cl. 257/705; 257/729; 257/678

(57) ABSTRACT

A circuit substrate includes a carrier, at least one non-conductive diamond-like carbon layer provided on a top surface of the carrier, at least one conductive film-coating layer provided on a surface of the non-conductive diamond-like carbon layer and in the form of a conductive logical circuitry, an upper non-conductive diamond-like carbon layer provided on a surface of the conductive film-coating layer, and a plurality of soldering pads downwardly extended through the upper non-conductive diamond-like carbon layer to bond to the conductive film-coating layer and serve as soldering points for connecting the conductive film-coating layer to external elements. The non-conductive diamond-like carbon layers provide super-high thermal conductivity and heat-radiating ability to enhance the heat-radiating ability of the circuit substrate, enabling the circuit substrate to have increased transmission and operation rates and prolonged usable life.

### FIELD OF THE INVENTION

The present invention relates to a circuit substrate, and more particularly, to a circuit substrate having high thermal conductivity and high heat radiating ability.

### BACKGROUND OF THE INVENTION

A circuit substrate is a very important component in an electronic product, and its main function is to connect circuits and hold electronic elements thereon. That is, the circuit substrate provides a stable circuit environment to enable easy assembling of electronic elements.

Generally, a circuit substrate includes a carrier having a silicone insulating layer provided thereon, and a metal layer provided on the silicone insulating layer for forming logical circuitry on the metal layer. Electronic elements and components are mounted on the metal layer.

When the electronic elements and components process or transmit data, they consume electric energy which consequently produces heat and raises the temperature significantly. An overly high temperature reduces the data transmission and operation rates of the electronic product or even burns out the electronic components. Therefore, the heat-radiating ability of the circuit substrate is an important factor having influence on the performance and life of the electronic product. It is therefore an important issue for related manufacturers to enhance the heat radiating effect of the circuit substrate.

Generally, the circuit substrate utilizes the insulating and radiating ability of silicone in the silicone insulating layer to dissipate heat produced by the electronic elements and components. In recent years, it has been found that a diamond-like carbon film coating has even better heat radiating ability than the silicone electrical insulating material.

The diamond-like carbon film coating, either non-conductive or conductive, has super-high thermal conductivity and super-high heat radiating ability.

Therefore, it is intended by the inventor to develop a circuit substrate that employs the diamond-like carbon film coating as a constituting element of the circuit substrate for the same to have increased heat-radiating ability.

### SUMMARY OF THE INVENTION

A primary object of the present invention is to provide a circuit substrate having largely enhanced heat-radiating ability.

Another object of the present invention is to provide a circuit substrate having a carrier, on which multiple layers of conductive logical circuitry may be constructed to expand the application of the circuit substrate.

To achieve the above and other objects, the circuit substrate according to the present invention includes a carrier, at least one non-conductive diamond-like carbon layer provided on a top surface of the carrier, at least one conductive film-coating layer provided on a surface of the non-conductive diamond-like carbon layer and in the form of a conductive logical circuitry, an upper non-conductive diamond-like carbon layer provided on a surface of the conductive film-coating layer, and a plurality of soldering pads downward extended through the upper non-conductive diamond-like carbon layer to bond to the conductive film-coating layer and serve as soldering points for connecting the conductive film-coating layer to external elements. The non-conductive diamond-like carbon layers provide super-high thermal conductivity and heat-radiating ability to enhance the heat-radiating ability of the circuit substrate, enabling the circuit substrate to have increased transmission and operation rates and prolonged usable life.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a sectional view of a circuit substrate according to a first embodiment of the present invention;

FIG. 2 is a sectional view of a circuit substrate according to a second embodiment of the present invention; and

FIG. 3 is a sectional view of a circuit substrate according to a third embodiment of the present invention.

### DETAILED DESCRIPTION OF THE PREFERRED EMBODIMENTS

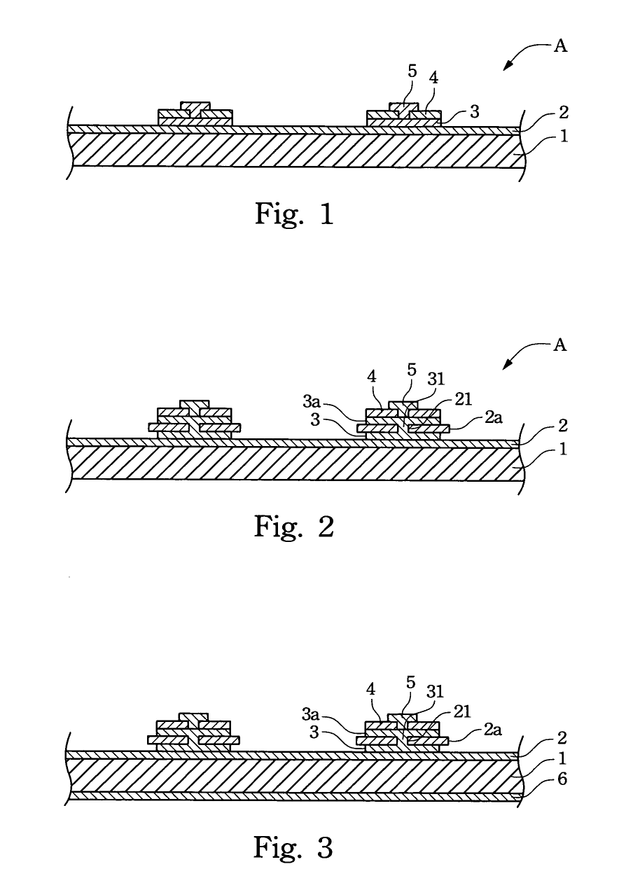

Reference is made to FIG. 1 that is a sectional view of a circuit substrate A according to a first embodiment of the present invention. As shown, the circuit substrate A includes a carrier 1, a non-conductive diamond-like carbon layer 2, a conductive film-coating layer 3, an upper non-conductive diamond-like carbon layer 4, and a plurality of soldering pads 5.

The carrier 1 may be a metal carrier or a non-metal carrier. In the case of a metal carrier, the carrier 1 is made of a metal material with high thermal conductivity and high heat-radiating ability, such as copper, aluminum, or any alloy thereof.

The non-conductive diamond-like carbon layer 2 is provided on a top surface of the carrier 1 by way of, for example, a spray-on process.

The conductive film-coating layer 3 is provided on a surface of the non-conductive diamond-like carbon layer 2, and is in the form of a conducting logical circuitry. The conductive film-coating 3 may be a conductive diamond-like carbon or a conductive metal film coating. In the case of a conductive metal film coating, it may be a film coating of copper, aluminum, or any alloy thereof.

The upper non-conductive diamond-like carbon layer 4 is provided on a surface of the conductive film-coating layer 3 to serve as an insulating layer.

Each of the soldering pads 5 is extended through the upper non-conductive diamond-like carbon layer 4 to bond to the conductive film-coating layer 3 and serve as a soldering point for electrically connecting the conductive film-coating layer 3 to external elements. That is, the soldering pad 5 serves as a soldering point for connecting the logical circuitry on the conductive film-coating layer 3 to external elements.

In the above-described circuit substrate A, since the non-conductive diamond-like carbon layer 2 and the conductive film-coating layer 3, which may be a conductive diamond-like carbon layer, provided on the top surface of the carrier 1 both have very high thermal conductivity and very good heat-radiating ability, they largely increase the heat-radiating ability of the whole circuit substrate A, enabling the circuit substrate A to have increased transmission and operation rates as well as prolonged usable life.

FIG. 2 is a sectional view of a circuit substrate A according to a second embodiment of the present invention. In the circuit substrate A of the first embodiment, only one non-conductive diamond-like carbon layer 2 and only one conductive film-coating layer 3 are provided. However, in the circuit substrate A of the second embodiment, more than one non-conductive diamond-like carbon layer and more than one conductive film-coating layer are provided to form more than one layer of logical circuitry.

As shown in FIG. 2, in addition to the non-conductive diamond-like carbon layer 2 provided on the top surface of the carrier 1 and the conductive film-coating layer 3 provided on the non-conductive diamond-like carbon layer 2, there are still an additional upper non-conductive diamond-like carbon layer 2a provided on the conductive film-coating layer 3 and an additional upper conductive film-coating layer 3a provided on the upper non-conductive diamond-like carbon layer 2a. The upper non-conductive diamond-like carbon layer 2a provided between the upper conductive film-coating layer 3a and the conductive film-coating layer 3 has a plurality of through-holes 21 formed thereon. A conductive body 31 is set in each of the through holes 21 to electrically connect the two conductive film-coating layers 3 and 3a to each other. With the alternately stacked non-conductive diamond-like carbon layers 2 and 2a and conductive film-coating layers 3 and 3a, multiple layers of logical circuitry may be constructed on the carrier 1 to expand the function of the circuit substrate A. The circuit substrate A in the second embodiment of the present invention provides the same good heat-radiating effect as the first embodiment.

Reference is made to FIG. 3 that is a sectional view of a circuit substrate according to a third embodiment of the present invention. The third embodiment is generally structurally similar to the second embodiment, except for a super-high thermal conductivity diamond-like carbon layer 6 provided at a bottom surface of the carrier 1. The super-high thermal conductivity diamond-like carbon layer 6 downwardly conducts heat from the bottom surface of the carrier 1 to thereby further enhance the heat-radiating effect of the circuit substrate.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A circuit substrate, comprising:
a carrier;
at least one non-conductive diamond-like carbon layer provided on a top surface of said carrier;
at least one conductive film-coating layer provided on a surface of said at least one non-conductive diamond-like carbon layer, and being in the form of a conductive logical circuitry;
an upper non-conductive diamond-like carbon layer provided on a surface of said at least one conductive film-coating layer; and
a plurality of soldering pads downwardly extended through said upper non-conductive diamond-like carbon layer to bond to said at least one conductive film-coating layer, said soldering pads serving as soldering points for electrically connecting said at least one conductive film-coating layer to external elements.

2. The circuit substrate as claimed in claim 1, wherein said carrier is made of a metal material.

3. The circuit substrate as claimed in claim 2, wherein said metal material is selected from the group consisting of copper, aluminum, and alloys thereof.

4. The circuit substrate as claimed in claim 1, wherein said carrier is made of a non-metal material.

5. The circuit substrate as claimed in claim 1, wherein said at least one conductive film-coating layer is a conductive diamond-like carbon layer.

6. The circuit substrate as claimed in claim 1, wherein said at least one conductive film-coating layer is a conductive metal film-coating layer.

7. The circuit substrate as claimed in claim 6, wherein said conductive metal film-coating layer is formed from a metal material selected from the group consisting of copper, aluminum, and alloys thereof.

8. The circuit substrate as claimed in claim 1, wherein said carrier is provided at a bottom surface with a super-high thermal conductivity diamond-like carbon layer.

9. The circuit substrate as claimed in claim 1, further comprising an upper non-conductive diamond-like carbon layer provided on the surface of said at least one conductive film-coating layer, and an upper conductive film-coating layer provided on and downwardly extended through a surface of said upper non-conductive diamond-like carbon layer to connect with said at least one conductive film-coating layer; and said upper conductive film-coating layer, said upper non-conductive diamond-like carbon layer, said at least one conductive film-coating layer, and said at least non-conductive diamond-like carbon layer being alternately stacked on said top surface of said carrier, allowing multiple layers of logical circuitry to form on said carrier.

10. The circuit substrate as claimed in claim 8, further comprising an upper non-conductive diamond-like carbon layer provided on the surface of said at least one conductive film-coating layer, and an upper conductive film-coating layer provided on and downwardly extended through a surface of said upper non-conductive diamond-like carbon layer to connect with said at least one conductive film-coating layer; and said upper conductive film-coating layer, said upper non-conductive diamond-like carbon layer, said at least one conductive film-coating layer, and said at least non-conductive diamond-like carbon layer being alternately stacked on said top surface of said carrier, allowing multiple layers of logical circuitry to form on said carrier.
